(19) United States
(12) Patent Application Publication
(10) Pub. No.: US 2023/0246409 A1
(43) Pub. Date: Aug. 3, 2023

(54) Method and Device for Stabilizing Electromagnetic Radiation from an Optical Oscillator

(71) Applicant: Menlo Systems GmbH, Martinsried (DE)

(72) Inventors: Nikolai LILIENFEIN, München (DE); Wolfgang HÄNSEL, München (DE); Ronald HOLZWARTH, Gröbenzell (DE); Simon HOLZBERGER, Veitsbronn (DE); Marc FISCHER, München (DE); Frederik BÖHLE, München (DE)

(21) Appl. No.: 18/103,767

(22) Filed: Jan. 31, 2023

(30) Foreign Application Priority Data
Feb. 1, 2022 (DE) 102022102272.2

(51) Int. Cl. H01S 3/139; H01S 3/13

(52) U.S. Cl. CPC H01S 3/1394; H01S 3/1305

(57) ABSTRACT

Stabilizing an electromagnetic radiation (1) of an optical oscillator (3), in particular of a laser (13), includes measuring a deviation (35, 37, 43) between the electromagnetic radiation (1) of the optical oscillator (3) and a reference (21, 23, 39, 41) and generating a first deviation signal (35, 37, 43), controlling a first controller (55) with the first deviation signal (35, 37, 43), setting the first deviation signal (35, 37, 43, 38) by controlling at least a first manipulated variable (5, 7, 89) of at least two manipulated variables (5, 7, 89), the first manipulated variable (5, 7, 89) being controlled by a first output signal (57) of the first controller (55) and the first manipulated variable (5, 7, 89) affecting the first electromagnetic radiation (1) of the optical oscillator (3), and generating a modulation signal (65) with a modulation unit (63), and controlling the first or a second manipulated variable (5, 7, 89) with the modulation signal (65), demodulating the first output signal (57) of the first controller (55) with the modulation signal (65) and generating a second deviation signal (71) from a fixed value (73), controlling a second controller (74) with the second deviation signal (71) and controlling one of the manipulated variables (5, 7, 89) with an output signal (75) of the second controller (74) and setting the second deviation signal (71).

The invention relates to a method as well as to a device, in particular a control device, for stabilizing a first electromagnetic radiation of an optical oscillator, in particular a first laser, having the features according to the preamble of claims 1, 15 and 16, respectively.

Methods or devices, in particular control devices, of the type referred to above are often used in spectroscopic methods, such as absorption spectroscopy of atoms or molecules, or in medical methods. Here, it is desired to at least generate electromagnetic radiation with the smallest possible wavelength deviation or frequency deviation from a reference. It is of particular interest to further improve already existing methods or devices, especially control devices, in order to achieve a better stabilization of electromagnetic radiation of an optical oscillator, especially a laser. The aim is also to achieve the simplest possible implementation for this purpose in order to enable the most general benefit possible.

For example, Chiow et al. “Extended-cavity diode lasers with tracked resonances,” Applied Optics, Volume 46, page 7997, publication year 2007, describe modulating a manipulated variable of a diode laser, measuring the intensity or frequency noise of the electromagnetic radiation of the diode laser, and controlling the intensity or frequency noise by controlling the manipulated variable to achieve stabilization of the radiation of the diode laser.

US 2009/0262762 A1 and U.S. Pat. No. 6,687,269 B1 describe modulating a manipulated variable of a laser, measuring its light intensity, and controlling the laser to maximize the light intensity.

US 2008/0159340 A1 describes the control of a transmission of a laser to achieve a stabilization of the radiation of the laser.

It is the object of the invention to provide a method or a device, in particular a control device, for stabilizing electromagnetic radiation of an optical oscillator, in particular a laser, e.g. a diode laser with external resonator, wherein the method and the device, respectively, in particular the control device, is to provide a particularly stable potential to generate radiation with at least one wavelength or frequency that is as constant as possible with respect to a reference, as well as to avoid mode jumps, in particular of the laser, e.g. the diode laser with external resonator.

This object is addressed according to the invention by a method according to claims 1 and 16, respectively, as well as by a device, in particular a control device, according to claim 15 for stabilizing electromagnetic radiation of an optical oscillator, in particular a laser.

The technical effect achieved here is to provide improved stabilization of electromagnetic radiation from an optical oscillator, in particular a laser.

Preferably, one of a plurality of manipulated variables may be controlled by an output signal of a controller and a frequency or phase deviation signal of the electromagnetic radiation of the optical oscillator may be controlled.

Preferably, a ratio of modulation indices, in particular frequency or phase modulation indices, of at least two manipulated variables may be measured and a deviation signal may be generated from a deviation of the ratio from a fixed value and, furthermore, one of the manipulated variables may be controlled with an output signal of a controller and the deviation signal or the ratio may be controlled. In this way, conditions may be created so as to provide a dynamic range for at least one manipulated variable of the optical oscillator.

Further preferably, a frequency or phase modulation index of at least one manipulated variable may be measured and a deviation signal may be generated from a deviation of the frequency or phase modulation index from a fixed value and furthermore the manipulated variable may be controlled with an output signal of a controller and the deviation signal may be set. In this way, conditions may be created so as to provide a dynamic range for at least one manipulated variable of the optical oscillator.

A modulation index is to be understood as the ratio between the controlling of a manipulated variable and the effect of the manipulated variable on the electromagnetic radiation. Correspondingly, a frequency modulation index is to be understood as the controlling of a manipulated variable and the effect of the manipulated variable on a frequency of the electromagnetic radiation. Further correspondingly, a phase modulation index is to be understood as the controlling of a manipulated variable and the effect of the manipulated variable on a phase of the electromagnetic radiation.

Advantageously, by controlling a ratio between a modulation index of a second manipulated variable and a modulation index of a first manipulated variable, a wide dynamic range may be provided for frequency or phase control of the optical oscillator. Thus, an improved stabilization of the electromagnetic radiation of the optical oscillator, in particular of the laser, may be achieved.

In the following, an electromagnetic radiation, for example generated by a laser or by different reference sources but also by other sources or generators that may generate an electromagnetic radiation, may include at least one frequency or equivalently at least one wavelength and the electromagnetic radiation may include at least one phase. Thus, if it is referred to generating a difference between different electromagnetic radiations, it is hereby meant that a frequency difference and/or a phase difference is generated. Hereby, an electromagnetic radiation may be generated that may include at least the aforementioned frequency difference and/or phase difference. If adjusting the electromagnetic radiation is referred to, hereby this may in particular mean that the frequency and/or the phase of the electromagnetic radiation is adjusted. However, an adjustment of an amplitude of the electromagnetic radiation may also be meant, in particular an adjustment of a field quantity or a power, wherein the field quantity may include a voltage, a current, an electric field or a magnetic field.

Controlling the electromagnetic radiation may correspondingly include controlling the at least one frequency or the at least one wavelength and/or may further include controlling at least the one phase.

Further in the following the concept of a wavelength and a frequency is used with the consideration that wavelength and frequency are in a fundamental relation to each other, according to which a product of wavelength and frequency corresponds to a velocity, where the velocity may be the speed of light. Here, the speed of light may be the speed of light in vacuum or the speed of light may be the speed of light in a medium, where the medium may be characterized by a refractive index and the speed of light in the medium may be slower than the speed of light in vacuum, where a slowing of the speed of light in the medium relative to the speed of light in vacuum may be quantified by dividing the speed of light in vacuum by the refractive index.

Preferably, all manipulated variables provided in the device according to the invention, in particular in the control device, and all manipulated variables provided in the method according to the invention, respectively, may be controlled by at least one controller, even if this is not explicitly mentioned. A manipulated variable may generally be controlled by several control signals, in particular by one or more controllers. When controlling a manipulated variable with several control signals, the control signals may be superimposed, in particular added. Thus, in particular, any provided manipulated variable may be used for stabilizing the electromagnetic radiation of the optical oscillator, in particular of a laser. Controlling may be direct, but may also be indirect, for example via a second controlling of other components of the device or the method. A manipulated variable may be generally configured to affect electromagnetic radiation for adjusting the electromagnetic radiation. In particular, a manipulated variable may be configured to affect a frequency and/or phase of the electromagnetic radiation for adjusting the frequency and/or phase of the electromagnetic radiation.

Preferably, the method according to the invention for stabilizing a first electromagnetic radiation of an optical oscillator, in particular a first laser, may include measuring a deviation between the first electromagnetic radiation of the optical oscillator and a reference and generating a first deviation signal, and may further include controlling a first controller with the first deviation signal, adjusting the first deviation signal by controlling at least a first manipulated variable of at least two manipulated variables, wherein the first manipulated variable may be controlled by a first output signal of the first controller and the first manipulated variable may affect the first electromagnetic radiation of the optical oscillator, and generating a modulation signal with a modulation unit, and controlling the first or a second manipulated variable with the modulation signal, demodulating the first output signal of the first controller with the modulation signal and generating a second deviation signal with respect to a fixed value, controlling a second controller with the second deviation signal, and controlling one of the manipulated variables with an output signal of the second controller and setting the second deviation signal.

As described above, setting the first deviation signal by controlling at least one first manipulated variable of at least two manipulated variables may include controlling with one or more control signals.

In one embodiment, the method may include setting the first deviation signal by means of controlling at least two manipulated variables, wherein the two manipulated variables may each be controlled by at least one output signal of the first controller and the two manipulated variables may act on the first electromagnetic radiation of the optical oscillator. In a preferred embodiment, the deviation may be minimized.

In a preferred embodiment, the reference may include a second electromagnetic radiation from a second laser and the deviation may be obtained as the difference between the first electromagnetic radiation and the second electromagnetic radiation.

In a preferred embodiment, the reference may include a radio frequency reference and a second electromagnetic radiation of a second laser, and the deviation may be obtained as a difference between, on the one hand, a difference of the first electromagnetic radiation and the second electromagnetic radiation, and, on the other hand, the radio frequency reference.

In a preferred embodiment, the deviation may include a frequency deviation or a phase deviation.

In one embodiment, the second laser may be a continuous wave laser.

The second laser may be configured as a Sagnac laser.

In one embodiment, the second laser may be a pulsed laser.

In one embodiment, the second laser may be a frequency comb laser.

In one embodiment, the second electromagnetic radiation may be a frequency comb generated by electro-optic modulation.

In one embodiment, the second electromagnetic radiation may be a frequency comb generated by nonlinear frequency conversion.

In a preferred embodiment, the reference may include a resonator and the deviation may include a frequency deviation or a phase deviation between a frequency or phase of the first electromagnetic radiation and a frequency or phase of the resonator.

In a preferred embodiment, the resonator may include a quality in a range between 10000 and 1000000, wherein the quality may be equal to a frequency of the resonator divided by a frequency bandwidth of the resonator. Preferably, the resonator may include ULE (ultra-low expansion) spacers.

Advantageously, the resonator may comprise a quality in a range between 50000 and 700000, wherein the quality may be equal to a frequency of the resonator divided by a frequency bandwidth of the resonator, and the resonator may preferably include ULE (ultra-low expansion) spacers. Further advantageously, the resonator may include a quality in a range between 100000 and 500000. Further advantageously, the resonator may include a quality in a range between 300000 and 500000.

In a preferred embodiment, the resonator may include an etalon. The etalon may be configured differently and designed according to its function in the method and/or the resonator. In particular, the etalon may be a Fabry-Perot etalon.

In a preferred embodiment, the resonator may include an interferometer.

The interferometer may be configured as a fiber interferometer, in particular as a fiber free-space interferometer.

The interferometer may be configured as a free-beam interferometer.

The interferometer may be configured as a Fizeau interferometer.

The interferometer may be configured as a Fabry-Perot interferometer.

The interferometer may be configured as a Sagnac interferometer.

The interferometer may be configured as a Michelson interferometer. The Michelson interferometer can include two interferometer arms of different lengths, in particular of different optical or geometric lengths.

In a preferred embodiment, the reference may include an atomic or molecular gas and the deviation may include a frequency deviation or a phase deviation between a frequency or phase of the first electromagnetic radiation and a frequency or phase of a resonance of the atomic or molecular gas. A measurement of the frequency deviation or the phase deviation may include saturation spectroscopy or Ramsey spectroscopy.

In one embodiment, the reference may include an atomic beam or atomic beam interferometer and the deviation may include a frequency deviation or a phase deviation between a frequency or phase of the first electromagnetic radiation and a frequency or phase of a resonance of the atomic beam or atomic beam interferometer.

In one embodiment, the reference may include laser cooled atoms or ions and the deviation may include a frequency deviation or a phase deviation between a frequency or phase of the first electromagnetic radiation and a frequency or phase of a resonance of the atoms or ions.

In a preferred embodiment, the reference may include a frequency or phase measurement instrument, in particular a wavemeter or an interferometer, and the deviation may include a frequency deviation or a phase deviation between a frequency or phase of the first electromagnetic radiation and a frequency or phase of the frequency or phase measurement instrument.

In a preferred embodiment, the optical oscillator may include the manipulated variables and may include a semiconductor laser, in particular a diode laser, and the manipulated variables may include the diode current of the diode laser and/or may include the diode temperature of the diode laser. A manipulated variable may be a parameter or an actuator.

The diode laser may be provided with an external resonator. The frequency and/or phase of the first electromagnetic radiation may be stabilized with respect to a reference system. The reference system may include an optical oscillator, wherein the optical oscillator of the reference system may be implemented as a reference-configuring component.

The first electromagnetic radiation of the external cavity diode laser may be stabilized with respect to the reference system by means of electromagnetic radiation of a frequency comb.

The diode laser may include a laser diode, wherein the laser diode may be provided with an anti-reflective coating. The anti-reflective coating may include a reflectance in a range between 1×10\hat{ }-5 and 1×10\hat{ }-1. The anti-reflective coating may include a reflectance in a range between 1×10\hat{ }-3 and 1×10\hat{ }-1.

The diode laser may include a laser diode, and the laser diode may be configured to be free of anti-reflective coatings.

In one embodiment, the optical oscillator may include a distributed Bragg reflector (DBR) or distributed feedback (DFB) semiconductor laser.

In one embodiment, the optical oscillator may include an optically pumped semiconductor laser, and the manipulated variables may include the optical power of a pump laser. In particular, the optically pumped semiconductor laser may be a vertical-external-cavity surface-emitting laser (VECSEL).

In one embodiment, the optical oscillator may be implemented as a photonic integrated circuit in one or more semiconductor elements.

In one embodiment, the optical oscillator may be implemented as a heterogeneously integrated photonic circuit in multiple semiconductor elements.

In a preferred embodiment, the optical oscillator may include a semiconductor laser. The semiconductor laser may emit electromagnetic radiation, wherein the electromagnetic radiation may include a wavelength between 350 nm and 10 microns, in particular between 350 nm and 1500 nm, in particular between 350 nm and 550 nm, in particular between 600 nm and 800 nm.

In a preferred embodiment, the optical oscillator may include a first surface and a second surface, wherein at least one of the first surface and the second surface may be partially transmissive to the first electromagnetic radiation, and the optical oscillator may include an adjustable wavelength filter for selecting at least one wavelength of the first electromagnetic radiation.

In a preferred embodiment, the manipulated variables may include at least one piezo actuator that may be coupled to the first surface and/or the second surface to exert a force on the first surface and/or the second surface to adjust the frequency or phase of the first electromagnetic radiation. In particular, the piezo actuator may be configured to provide continuous adjustment of the frequency or phase of the first electromagnetic radiation. In one embodiment, the manipulated variables may include the adjustable wavelength filter and may be configured to adjust the adjustable wavelength filter.

In one embodiment, the manipulated variables may include at least one electro-optic modulator that may be disposed in a beam path of the laser to adjust the frequency or phase of the first electromagnetic radiation. In one embodiment, at least one of the manipulated variables may be external to the optical oscillator and include an acousto-optic modulator or a frequency shifter.

Preferably, a device according to the invention for stabilizing a first electromagnetic radiation from an optical oscillator, in particular a first laser, may include a control device.

Preferably, the control device may include a measuring device, a reference generator for generating a reference, a first controller and a second controller. In particular, the measuring device may be configured to measure a deviation between the first electromagnetic radiation of the optical oscillator and the reference, wherein the first controller may be configured to be controlled by a first deviation signal and to control or adjust the deviation signal by controlling at least a first manipulated variable of at least two manipulated variables with a first output signal.

Preferably, the control device can include a modulation unit, which may be configured to control the first or a second manipulated variable with a modulation signal.

Preferably, the control device may include a demodulation unit that may be configured to demodulate the first output signal of the first controller with the modulation signal and to generate a second deviation signal from a fixed value.

Preferably, the second controller may be configured to be controlled by the second deviation signal and to control one of the manipulated variables with an output signal so as to control or adjust the second deviation signal.

The invention may include a method for stabilizing a first electromagnetic radiation of an optical oscillator, in particular a laser, which may include measuring a deviation between the first electromagnetic radiation of the optical oscillator and a reference and generating a first deviation signal. The method may include controlling a first controller with the first deviation signal. The method may include controlling or adjusting the first deviation signal by controlling at least a first manipulated variable of at least two manipulated variables, wherein the first manipulated variable may be controlled by a first output signal of the first controller and the first manipulated variable may act on the first electromagnetic radiation of the optical oscillator. In particular, the method may include measuring a modulation index, in particular a frequency and/or phase modulation index, of at least one of the manipulated variables. The method may include generating a second deviation signal from a deviation of the modulation index from a fixed value. The method may include controlling a second controller with the second deviation signal. The method may include controlling one of the manipulated variables with an output signal of the second controller. The method may include controlling or adjusting the second deviation signal or the modulation index, wherein the modulation index is a ratio of controlling at least one of the manipulated variables and the effect of the at least one manipulated variable on the first electromagnetic radiation.

In one embodiment, the method may include controlling or adjusting the first deviation signal by controlling at least two manipulated variables, wherein the two manipulated variables may each be controlled by an output signal of the first controller and the two manipulated variables may act on the first electromagnetic radiation of the optical oscillator.

The invention may include a method for stabilizing a first electromagnetic radiation of an optical oscillator, in particular a laser, which may include measuring a deviation between the first electromagnetic radiation of the optical oscillator and a reference and generating a first deviation signal, and further include controlling a first controller with the first deviation signal and adjusting the first deviation signal by controlling at least a first manipulated variable of at least two manipulated variables, wherein the first manipulated variable may be controlled by a first output signal of the first controller and the first manipulated variable may act on the first electromagnetic radiation of the optical oscillator. In particular, the method may include generating a modulation signal with a modulation unit, and controlling the first or a second manipulated variable with the modulation signal, and may further include measuring a ratio from controlling manipulated variables and generating a second deviation signal from a deviation of the ratio from a fixed value, controlling a second controller with the second deviation signal, and controlling one of the manipulated variables with an output signal of the second controller and adjusting the second deviation signal or the ratio.

A method according to the invention may include generating a phase deviation signal and/or a frequency deviation signal by means of a comparison unit between, on the one hand, a difference of electromagnetic radiation of the optical oscillator and electromagnetic radiation of a first reference source, and, on the other hand, electromagnetic radiation of a second reference source, and may further include coupling the phase deviation signal and/or the frequency deviation signal into a first controller and controlling at least a first manipulated variable of the optical oscillator with at least an output signal of the first controller for adjusting the phase deviation signal and/or the frequency deviation signal, generating a modulation and generating at least one first superposition of the modulation with an output signal of a second controller, controlling at least one second manipulated variable of the optical oscillator different from the first manipulated variable with the at least one first superposition, generating a demodulation signal of the output signal of the first controller, and controlling the at least one first manipulated variable of the optical oscillator with a different second superposition from the output signal of the first controller and an output signal of a third controller controlled with the demodulation signal, and controlling a ratio between controlling the at least one second manipulated variable with the at least one first superposition and controlling the at least one first manipulated variable with the second superposition.

Advantageously, generating the phase deviation signal and/or the frequency deviation signal by means of the comparison unit may include a known device and/or a known method for generating a phase deviation signal and/or a frequency deviation signal.

Advantageously, the method may include the act of minimizing a phase deviation of the phase deviation signal and/or a frequency deviation of the frequency deviation signal between the difference of the electromagnetic radiation of the optical oscillator and the electromagnetic radiation of the first reference source, and the electromagnetic radiation of the second reference source.

Optionally, the method for stabilizing the electromagnetic radiation of the optical oscillator, in particular of the laser, may include a side-of-fringe locking frequency stabilization, wherein at least one frequency of the laser may be detuned with respect to a resonance frequency of a cavity or an atomic or molecular absorption line, wherein for this purpose the cavity may be provided with a first input and a first output, or a gas cell may be provided with an atomic or molecular gas and a first input and a first output, wherein the electromagnetic radiation of the optical oscillator, in particular of the laser, may be coupled into the first input of the cavity or into the first input of the gas cell, and the electromagnetic radiation of the optical oscillator, in particular of the laser, coupled out of the first output of the cavity or the first output of the gas cell may be detected by a detector. The detector may in particular be a photodetector, wherein further fluctuations of the at least one frequency of the laser may be converted into intensity fluctuations of an output signal of the detector, in particular of the photodetector, wherein the intensity fluctuations may be minimized by an additionally provided feedback loop, wherein the feedback loop may include at least the first manipulated variable or the second manipulated variable and may further include the output signal of the detector, in particular of the photodetector.

Optionally, the method for stabilizing the electromagnetic radiation of the optical oscillator, in particular the laser, may include a top-of-fringe locking frequency stabilization, wherein the at least one frequency of the laser may be modulated with a modulation frequency. The electromagnetic radiation of the laser may further be detected by a detector, in particular by a photodetector, at an input of the detector, in particular of the photodetector, wherein a modulation of the at least one frequency of the laser may cause an output signal of the detector, in particular of the photodetector, to be modulated as well. In this case, the output signal of the detector, in particular of the photodetector, may be modulated in particular with the modulation frequency, with which the at least one frequency of the laser is also modulated. Furthermore, a modulation of the output signal of the detector, in particular of the photodetector, may be demodulated with the modulation frequency, with which the at least one frequency of the laser may be modulated, for generating a derivative of a signal that may be generated by the electromagnetic radiation of the laser at the input of the detector, in particular of the photodetector.

The modulation of the at least one frequency of the laser may result in a positive or negative numerical value of the derivative, wherein the top-of-fringe locking frequency stabilization may be configured to minimize the magnitude of the numerical value of the derivative. Preferably, the top-of-fringe locking frequency stabilization may further include a feedback loop, wherein the feedback loop may include an input and an output, wherein the positive or negative numerical value of the derivative may be coupled into the input of the feedback loop and the output of the feedback loop may adjust the first manipulated variable and/or the second manipulated variable to minimize the magnitude of the numerical value of the derivative.

In an advantageous embodiment of the method, the optical oscillator may include a semiconductor laser, in particular a diode laser.

The diode laser may include a laser diode, wherein the laser diode may be provided with an anti-reflective coating or without an anti-reflective coating.

Advantageously, the semiconductor laser may include a first surface and a second surface.

Further, the electromagnetic radiation may be coupled out of the first surface and/or the second surface of the semiconductor laser, or the electromagnetic radiation may be at least partially coupled out of the first surface and/or the second surface of the semiconductor laser.

Advantageously, the electromagnetic radiation may be coupled out of the first surface of the semiconductor laser or the electromagnetic radiation may be at least partially coupled out of the first surface of the semiconductor laser.

When the electromagnetic radiation is coupled out of the first surface of the semiconductor laser, the second surface of the semiconductor laser may be of reflective configuration.

In particular, the second surface of the half-waveguide laser may be at least partially transmissive to the electromagnetic radiation.

In an advantageous embodiment of the method, the optical oscillator may include a cavity, wherein the cavity may include a first surface and a second surface, wherein at least the first surface of the cavity may be partially transmissive to the electromagnetic radiation. Alternatively, however, the second surface of the cavity may be partially transmissive to the electromagnetic radiation. Further, both the first surface and the second surface of the cavity may be partially transmissive to the electromagnetic radiation.

In particular, the electromagnetic radiation may include at least one wavelength, and advantageously, a length of the cavity may be greater than the at least one wavelength of the electromagnetic radiation.

In an advantageous embodiment, the optical oscillator may include an adjustable wavelength filter for selecting the at least one wavelength or for selecting the at least one frequency of the electromagnetic radiation, wherein the wavelength filter may be formed in the cavity, wherein an adjustment of the adjustable wavelength filter may be a further manipulated variable of the optical oscillator. By means of the aforementioned wavelength filter, at least one desired frequency of the electromagnetic radiation of the laser or of the semiconductor laser, in particular of the diode laser, may be selected or, equivalently, at least one desired wavelength of the electromagnetic radiation of the laser or of the semiconductor laser, in particular of the diode laser, may be selected.

Advantageously, the adjustable wavelength filter may include a volume holographic Bragg grating (VHBG), wherein selecting the at least one wavelength of electromagnetic radiation may include tilting the VHBG with respect to a propagation direction of the electromagnetic radiation.

Advantageously, the adjustable wavelength filter may include a frequency-selective or wavelength-selective grating, wherein a selection of the at least one wavelength of the electromagnetic radiation may be achieved by tilting the frequency-selective grating with respect to a propagation direction of the electromagnetic radiation, or equivalently a selection of the at least one frequency of the electromagnetic radiation may be achieved by tilting the frequency-selective grating with respect to a propagation direction of the electromagnetic radiation

Advantageously, the adjustable wavelength filter may include a dielectric filter, wherein selecting the at least one wavelength or selecting the at least one frequency of electromagnetic radiation may include tilting the dielectric filter with respect to a propagation direction of the electromagnetic radiation.

In particular, selecting the at least one wavelength or the at least one frequency of the electromagnetic radiation by means of the adjustable wavelength filter may include changing a temperature of the adjustable wavelength filter to achieve expansion or to achieve contraction of the adjustable wavelength filter to select the at least one wavelength of the electromagnetic radiation, wherein at least one structure of the adjustable wavelength filter may be displaced or deformed, wherein a length of the at least one structure of the wavelength filter may be adapted to the at least one wavelength of the electromagnetic radiation, or the length of the structure of the wavelength filter may be adapted to a half wavelength of the electromagnetic radiation, or the length of the structure of the wavelength filter may be adapted to a quarter wavelength of the electromagnetic radiation. Advantageously, the length of the structure of the wavelength filter may be adapted to any length of the wavelength of the electromagnetic radiation.

Adjustment of the adjustable wavelength filter may be another manipulated variable of the optical oscillator.

Advantageously, in the method of stabilizing the electromagnetic radiation, the length of the cavity may be adjustable, wherein the first surface and/or the second surface of the cavity may be coupled to an actuator, and the actuator may be configured to act on the first surface and/or the second surface to adjust the length, thereby adjusting the at least one wavelength of the electromagnetic radiation, wherein the at least second manipulated variable may include an action of the actuator on the first surface and/or the second surface.

In particular, by adjusting the length of the cavity, a coupling between the semiconductor laser, in particular the diode laser, and the cavity may be adjusted. Here, the semiconductor laser, in particular the diode laser, may excite one electromagnetic mode or a plurality of electromagnetic modes of the cavity at a predetermined length of the cavity, wherein the electromagnetic mode or the plurality of electromagnetic modes may include the at least one wavelength, whereas an excitation of further wavelengths may be suppressed. In this way, adjustment of the at least one wavelength of electromagnetic radiation may be achieved.

In particular, the actuator may be based on a piezoelectric effect or the actuator may be an electro-optic modulator.

Preferably, the cavity may be heatable via a temperature element for changing the length of the cavity by means of thermal expansion for adjusting the at least one wavelength of the electromagnetic radiation, wherein the thermal expansion of the cavity generated by the temperature element may represent a further manipulated variable of the optical oscillator.

Preferably, the cavity may be coolable via a temperature element for varying the length of the cavity by means of thermal contraction for adjusting the at least one wavelength of electromagnetic radiation, wherein the thermal contraction of the cavity produced by the temperature element may represent a further manipulated variable of the optical oscillator.

The temperature element may be arranged to heat only a partial area of the cavity. However, the temperature element may also be arranged to heat the cavity with a temperature that is at least largely homogeneously distributed over the cavity. The temperature element may include a temperature measuring device for controlling the temperature of the cavity, in particular for stabilizing the temperature of the cavity.

Advantageously, the semiconductor laser may be electronically pumped by an electric current. In this case, changing the absolute value of the electric current may result in a shortening or a lengthening of the at least one wavelength of the electromagnetic radiation and the at least first manipulated variable may include the electric current.

Advantageously, the semiconductor laser may be heatable for changing a geometry of the semiconductor laser for adjusting the at least one wavelength of the electromagnetic radiation, wherein changing the geometry of the semiconductor laser may represent another manipulated variable of the optical oscillator.

In an advantageous embodiment, generating the phase deviation signal and/or the frequency deviation signal by means of the comparison unit may include at least one wavelength conversion process for generating a frequency difference and/or a phase difference between the electromagnetic radiation of the optical oscillator and the electromagnetic radiation of the first reference source.

Here, the wavelength conversion process may be realized by the analog mixer.

Advantageously, the electromagnetic radiation of the first reference source may be generated by a frequency comb.

In an advantageous embodiment, the electromagnetic radiation of the second reference source may be adjustable and adaptable to the frequency difference and/or the phase difference between the electromagnetic radiation of the optical oscillator and the electromagnetic radiation of the first reference source.

In an advantageous embodiment, the electromagnetic radiation of the second reference source may include at least one frequency, wherein the frequency of the electromagnetic radiation of the second reference source may be set in a range from 500 kHz to 10 GHz, preferably in a range from 500 kHz to 1 GHz, preferably in a range from 500 kHz to 3 GHz, preferably in a range from 500 kHz to 5 GHz.

In an advantageous embodiment, the method according to the invention may be modified, wherein a modification of the method according to the invention includes deactivating the second controller, for switching off the output signal of the second controller, and providing a diode driver, and superimposing the modulation on the output signal of the third controller, for generating the first superimposition, instead of superimposing the output signal of the third controller on the output signal of the first controller, for generating the second superposition, wherein further an output signal of the diode driver may be superposed with the output signal of the first controller, for generating the second superposition, for controlling the at least one first manipulated variable of the optical oscillator, wherein the output signal of the diode driver may be a voltage and/or a current, wherein preferably the output signal of the diode driver may be a voltage pulse and/or a current pulse.

The device according to the invention may advantageously include a comparison unit including a wavelength converter and a wavelength comparator, and may further include a first reference source, a second reference source, a first controller, at least a first manipulated variable, the optical oscillator being configured to be controlled by the first manipulated variable, the comparison unit being configured to generate a phase deviation signal and/or a frequency deviation signal, wherein the wavelength converter is configured to generate a frequency difference and/or a phase difference between the electromagnetic radiation of the optical oscillator and an electromagnetic radiation of the first reference source, and the wavelength comparator compares the frequency difference and/or the phase difference between the electromagnetic radiation of the optical oscillator and the electromagnetic radiation of the first reference source with a frequency and/or phase of the electromagnetic radiation of the second reference source, to generate the phase deviation signal and/or the frequency deviation signal, wherein further the first controller is configured to receive the phase deviation signal and/or the frequency deviation signal to control the first manipulated variable with at least an output signal of the first controller to control or adjust the phase deviation signal and/or the frequency deviation signal, and may include a modulation unit to generate a modulation, and may include a first superposition unit to generate at least a first superposition of the modulation with an output signal of a second controller. Further, the device according to the invention may include a second manipulated variable, wherein the optical oscillator may be configured to be controlled by the second manipulated variable and the at least second manipulated variable may be configured to be controlled by the first superposition. In particular, the device according to the invention may include a demodulation unit that may be configured to generate a demodulation signal from the output signal of the first controller, wherein the demodulation unit may further be configured to control a third controller with the demodulation signal to generate an output signal of the third controller controlled by the demodulation signal. Preferably, the device according to the invention may include a second superposition unit that may be configured to control the at least one first manipulated variable of the optical oscillator with a second superposition, wherein the second superposition unit may be configured to generate the second superposition from the output signal of the first controller and the output signal of the third controller controlled by the demodulation signal. In particular, the device according to the invention may include a control unit, which may be configured to control a ratio between controlling the second manipulated variable and controlling the first manipulated variable.

In an advantageous embodiment of the device, an adjustable wavelength filter may be disposed in a cavity of the oscillator to select at least one wavelength of electromagnetic radiation, wherein the adjustable wavelength filter may be another manipulated variable of the optical oscillator.

In an alternative advantageous embodiment, the device according to the invention may be modified, wherein a modification of the device according to the invention includes the device without the second controller and without the output signal of the second controller, and may further include a diode driver, wherein the diode driver may be configured to generate an output signal, wherein the output signal of the diode driver may include a voltage and/or a current, advantageously wherein the output signal of the diode driver may include a voltage pulse and/or a current pulse, wherein the modification may further include the first superposition unit, wherein the first superposition unit may be configured to superimposing the modulation of the modulation unit on the output signal of the third controller to generate at least a first superposition, instead of having the second superposition unit to superimpose the output signal of the first controller on the output signal of the third controller to generate the second superposition, wherein the modification may further include the second superposition unit, wherein the second superposition unit may be configured to superpose the output signal of the diode driver with the output signal of the first controller to generate the second superposition to control the at least one first manipulated variable of the optical oscillator.

The diode driver may be configured to drive a laser and may be designed as an internal component of the laser. Preferably, the diode driver may be configured as an external component of the laser and may be coupled to the laser via an electronic connection.

The invention is explained below with reference to exemplary embodiments shown in the figures. In the figures

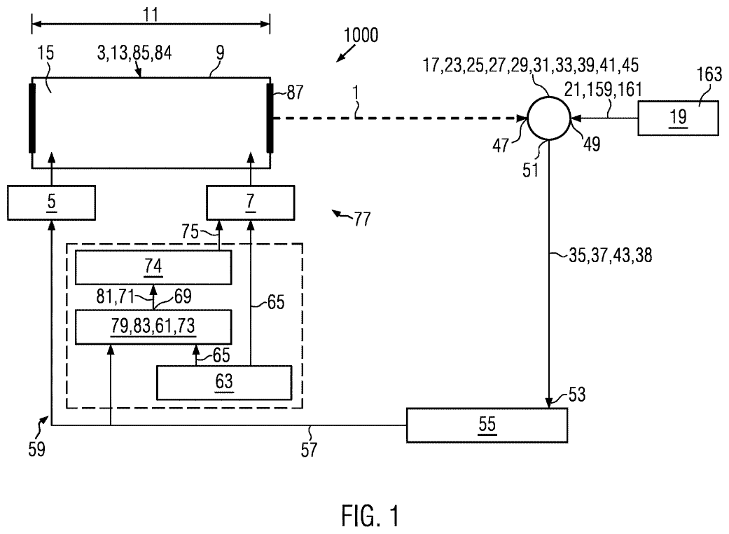

FIG. 1 is a schematic representation of controlling electromagnetic radiation according to a preferred embodiment of the method according to the invention or by means of a preferred embodiment of the device according to the invention;

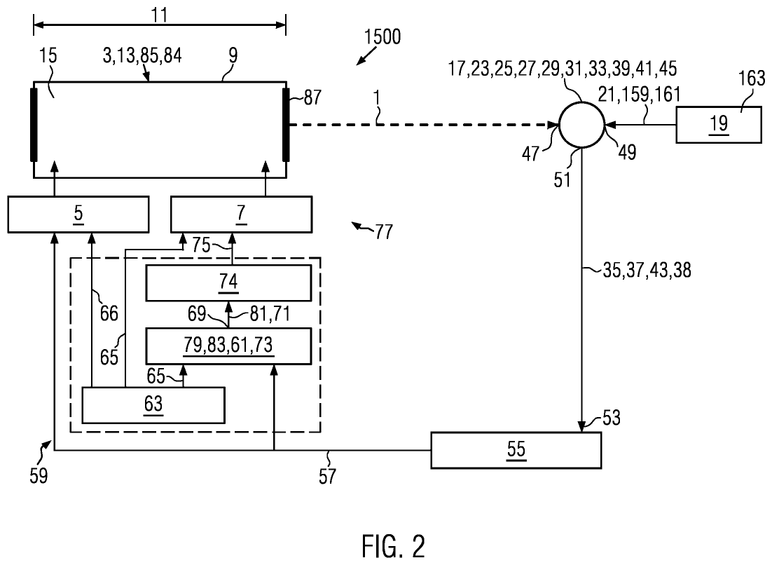

FIG. 2 is a schematic representation of controlling electromagnetic radiation according to a preferred embodiment of the method according to the invention or by means of a preferred embodiment of the device according to the invention;

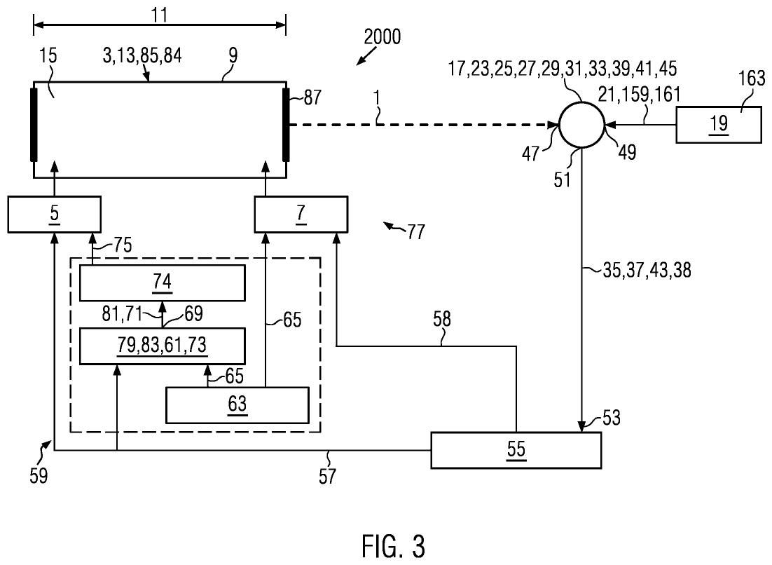

FIG. 3 is a schematic representation of controlling electromagnetic radiation according to a preferred embodiment of the method according to the invention or by means of a preferred embodiment of the device according to the invention;

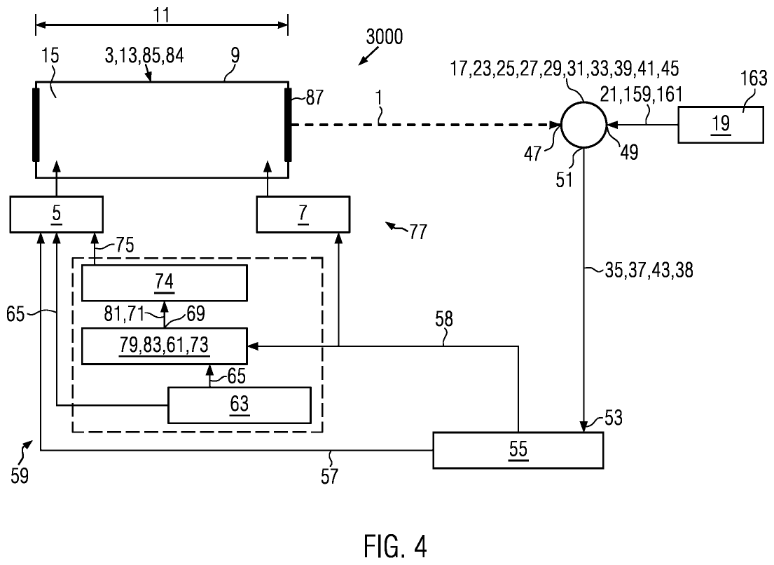

FIG. 4 is a schematic representation of controlling electromagnetic radiation according to a preferred embodiment of the method according to the invention or by means of a preferred embodiment of the device according to the invention;

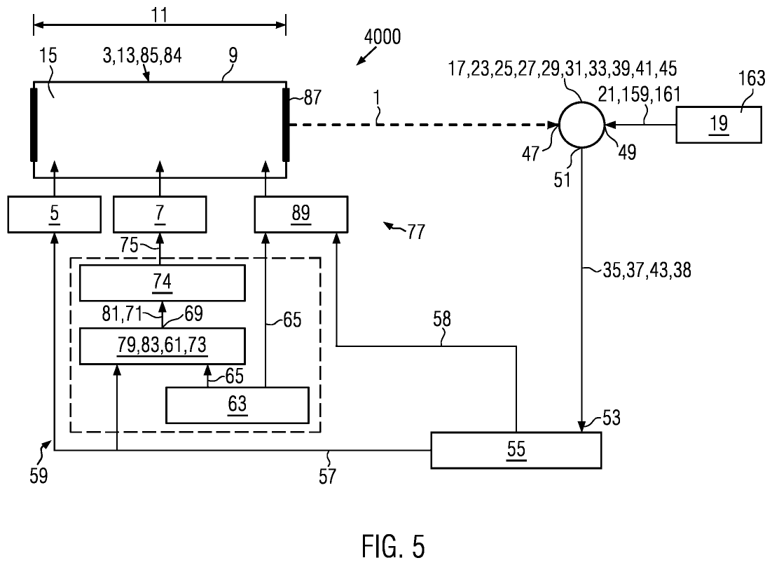

FIG. 5 is a schematic representation of controlling electromagnetic radiation according to a preferred embodiment of the method according to the invention or by means of a preferred embodiment of the device according to the invention;

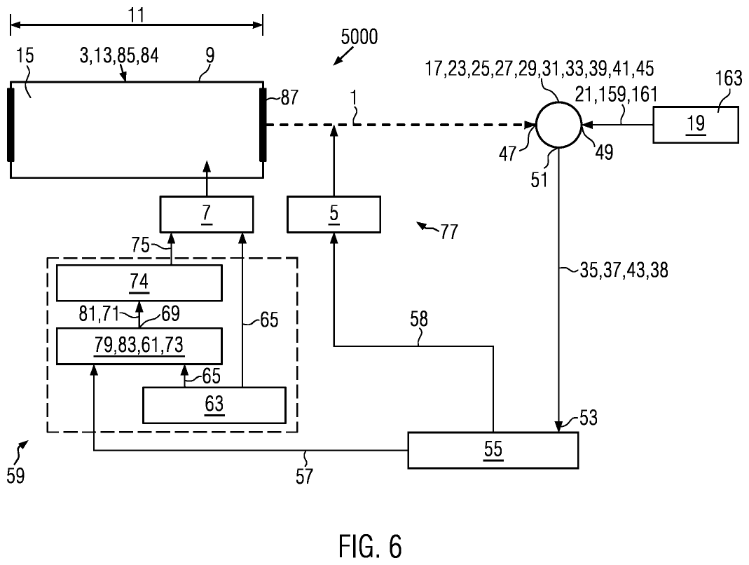

FIG. 6 is a schematic representation of controlling electromagnetic radiation according to a preferred embodiment of the method according to the invention or by means of a preferred embodiment of the device according to the invention;

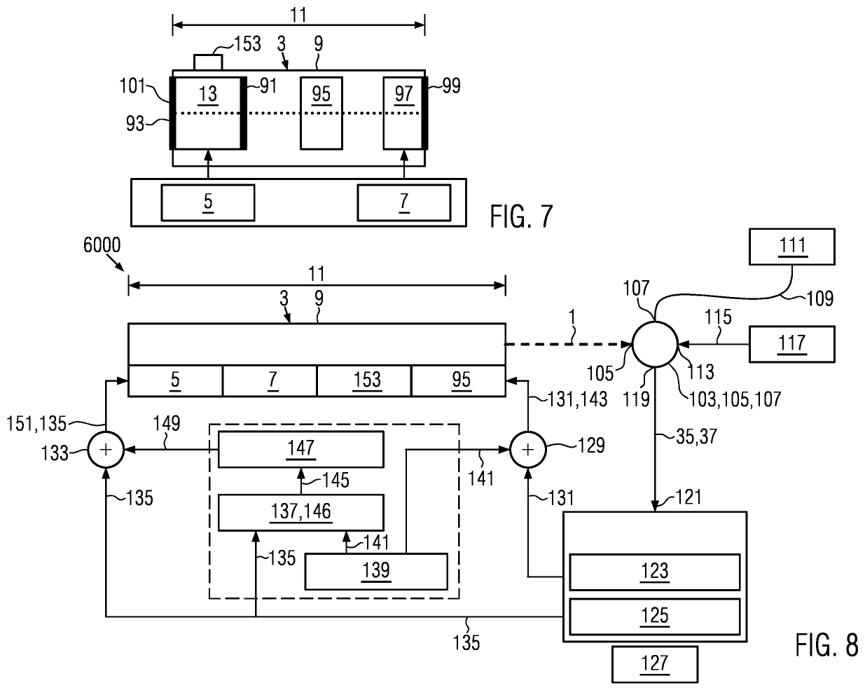

FIG. 7 is a schematic representation of an optical oscillator with two manipulated variables for generating and stabilizing electromagnetic radiation in accordance with a method according to the invention or by means of a device according to the invention;

FIG. 8 is a schematic representation of controlling electromagnetic radiation according to an advantageous embodiment of the method according to the invention or by means of an advantageous embodiment of the device according to the invention;

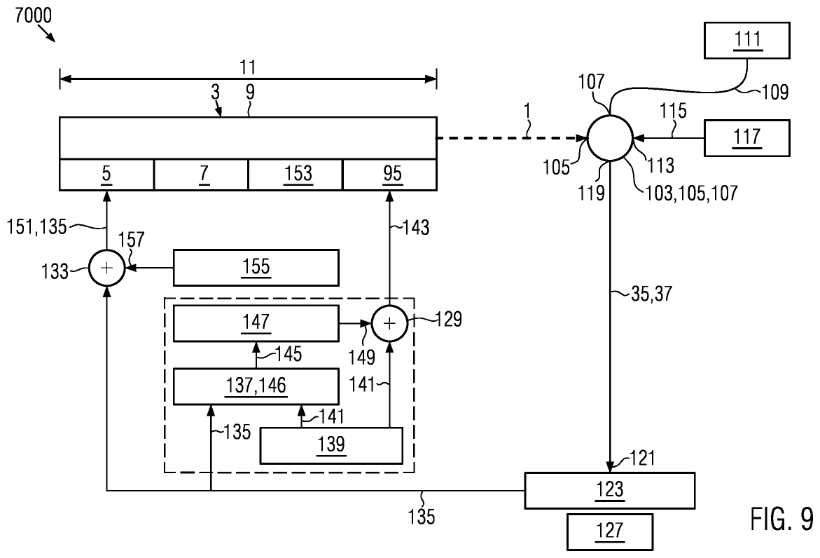

FIG. 9 is a schematic representation of controlling electromagnetic radiation according to an alternative advantageous embodiment of the method according to the invention or by means of an alternative advantageous embodiment of the device according to the invention.

Corresponding components are marked with the same reference signs in the figures and the detailed figure description below. Furthermore, alternative components with a corresponding effect, such as the components of the method for stabilizing electromagnetic radiation of an optical oscillator, in particular of a laser, described above and below, or of the device for stabilizing electromagnetic radiation of an optical oscillator, in particular of a laser, are considered interchangeable with the components of the same method or device described above and below.

FIG. 1 illustrates a preferred embodiment of a device 1000 according to the invention for stabilizing an electromagnetic radiation 1, which may enable a preferred method according to the invention for stabilizing the electromagnetic radiation 1 of an optical oscillator 3. The optical oscillator 3 may include a first manipulated variable 5 and a second manipulated variable 7. Further, the optical oscillator 3 may include a cavity 9, wherein the cavity 9 may have a length 11. Such an optical oscillator 3 is shown separately from the device 1000 in FIG. 7 and may be used as such in the device 1000, although geometrically differently arranged optical oscillators 3 or functionally differently arranged optical oscillators 3 may also be used in the device 1000. In particular, the optical oscillator 3 may be a laser. The optical oscillator 3 may be arranged in the preferred device 1000 according to the invention to generate the electromagnetic radiation 1. Here, the optical oscillator 3 may further include a semiconductor laser 13, wherein the semiconductor laser 13 may be arranged in an inner region 15 of the cavity 9. In this regard, the semiconductor laser 13 may excite at least one mode of the cavity 9. Furthermore, a measuring device 17 may be provided, wherein the measuring device 17 may be configured to receive the electromagnetic radiation 1. The measuring device 17 may be configured in various ways, as further described below.

Preferably, the measuring device 17 may include a reference generator 19 for generating a first reference 21. The first reference 21 may be in the form of a signal, in particular a reference signal 21. The reference signal 21 may include a frequency and/or phase.

Further preferably, the measuring device 17 may be configured as an independent measuring device for the electromagnetic radiation 1, and in this configuration the measuring device 17 may be configured as described below.

If the measuring device 17 is configured as an independent measuring device, i.e. without the reference generator 19, a reference signal may also be generated internally in the measuring device 17. For this purpose, the measuring device 17 configured as an independent measuring device may include a second reference 23 as a physical component. The second reference 23 as a physical component may be a measuring instrument or a further component for analyzing, measuring or processing the electromagnetic radiation 1.

In this regard, if the measuring device 17 is implemented as a stand-alone measuring device, the measuring device 17 may include various frequency selective elements, and in particular the various frequency selective elements, either individually or in combination, may form the aforementioned second reference 23 as a physical component. Advantageously, the various frequency selective elements may include a resonator 25, further advantageously an atomic or molecular gas 27, or further advantageously a frequency or phase measuring instrument 29 of any configuration but adapted to function in the device 1000, in particular a wavemeter 31 or an interferometer 33.

In particular, the frequency stabilization described above may include the resonator 25, the atomic or molecular gas 27, or the frequency or phase measurement instrument 29, especially the wavemeter 31 or the interferometer 33.

Preferably, the measuring device 17 may be configured to generate a phase deviation signal 35 and/or a frequency deviation signal 37 by comparing the electromagnetic radiation 1, in particular a phase or frequency of the electromagnetic radiation 3, with the first reference 21 and/or the second reference 23. The second reference 23 may here include a characteristic frequency 39, such as a resonance frequency 41, e.g. of the resonator 25.

Advantageously, the phase deviation signal 35 and/or the frequency deviation signal 37 may be signals that may be proportional to a difference 43 between the electromagnetic radiation 1 and the first reference 21 or the second reference 23, in particular the difference 43 may be defined between the electromagnetic radiation 1 and the reference signal 23 or the characteristic frequency 39. Advantageously, the phase deviation signal 35 and/or the frequency deviation signal 37 may be signals that may be proportional to a difference 38, wherein the difference 38 may be defined by taking a difference between the electromagnetic radiation 1 and the first reference 21 and subtracting the difference between the electromagnetic radiation 1 and the first reference 21 from the reference 23. A signal that is proportional to the difference 38 may also be referred to as a first deviation signal 38. In one embodiment, a signal that is proportional to the difference 43 may be considered as the first deviation signal 38. The difference 38 and the difference 43 may be electromagnetic signals, each of which may include a frequency and a phase.

The reference signal 23 may include a frequency and/or phase, and the characteristic frequency 39 may also include a phase. A difference may also be obtained between the electromagnetic radiation 1 and a frequency dependent quantity 45 of the first reference 21 or the second reference 23. Since the phase deviation signal 35 and/or the frequency deviation signal 37 may include the difference 38, or in embodiments may include the difference 43, the phase deviation signal 35 and/or the frequency deviation signal 37 may be considered as the first deviation signal 38.

In a preferred embodiment, the measuring device may include a first input 47, a second input 49 and a first output 51. Here, the electromagnetic radiation 1 may be coupled into the first input 47, the reference signal 21 may be coupled into the second input 49, and the phase deviation signal 35 and/or the frequency deviation signal 37 may be output at the first output 51.

The phase deviation signal 35 and/or the frequency deviation signal 37 may be coupled into a third input 53 of a first controller 55. Depending on the form of the phase deviation signal 35 and/or the frequency deviation signal 37, the first controller 55 may generate at least one output signal 57 to control a control loop 59. Here, the output signal 57 may drive or control the manipulated variable 5, wherein the manipulated variable 5 may act on the optical oscillator 3 and thus act on the electromagnetic radiation 1, for adjusting the electromagnetic radiation 1. In particular, the controller 55 may generate the output signal 57 to control a further controller when the difference 43 indicates that the electromagnetic radiation 1 deviates from the reference 21, in particular the reference signal 21, or when the difference 43 indicates that the electromagnetic radiation 1 deviates from the reference 23, in particular the characteristic frequency 39. In an advantageous embodiment, the controller 55 may generate the output signal 57 to control a further controller when the difference 38 indicates that the difference between the electromagnetic radiation 1 and the first reference 21 deviates from the reference 23.

The electromagnetic radiation 1 need not exactly match a reference, but a deviation from a constant offset value of the electromagnetic radiation 1 with respect to the reference may also be considered. The controller 55 may generate at least the output signal 57 when the difference 43 indicates that the electromagnetic radiation 1 deviates from the reference 23, in particular from the characteristic frequency 39, or deviates from the reference 21. In one embodiment, the controller 55 may generate at least the output signal 57 when the difference 38 indicates that the difference between the electromagnetic radiation 1 and the first reference 21 deviates from the reference 23. In particular, this may be the case if the difference 43 indicates that the electromagnetic radiation 1 does not deviate from the reference 21, in particular does not deviate from the reference signal 21, or if the difference 43 indicates that the electromagnetic radiation 1 does not deviate from the reference 23, in particular does not deviate from the characteristic frequency 39. The output signal 57 may include a finite value, in particular include a finite amplitude, but the output signal 57 may also be zero. The output signal 57 may be an electromagnetic signal or may include a constant current or a constant voltage, wherein the constant current may also be 0 amperes or the constant voltage may also be 0 volts. The output signal 57 may be coupled into a demodulation unit 61. Further, a modulation unit 63 may be provided to generate a modulation signal 65. The modulation signal 65 may be provided to the demodulation unit 61 to generate, at a second output 69, a second signal 71 indicating a deviation from a fixed value 73. The second deviation signal 71 may be provided to a second controller 74, wherein the second controller 74 may generate an output signal 75 and the output signal 75 may control the second manipulated variable 7 together with the modulation signal 65. In particular, the second manipulated variable 7 may act on the optical oscillator 3 and may thus act on the electromagnetic radiation 1, for adjusting the electromagnetic radiation 1. In particular, the two manipulated variables 5 and 7 may act together on the optical oscillator 3 and may thus act on the electromagnetic radiation 1, for adjusting the electromagnetic radiation 1. Here, the manipulated variable 5 may include a reaction time, which may be different from the reaction time of the manipulated variable 7. Here, the reaction time may be a time that elapses between the controlling of a manipulated variable and the effect of the manipulated variable on the optical oscillator 3. The response time of the manipulated variable 5 may be longer than the response time of the manipulated variable 7. In one embodiment, the response time of the manipulated variable 7 may also be longer than the response time of the manipulated variable 5. In this case, for stabilizing the first electromagnetic radiation 1, the second deviation signal 71 may be regulated.

In one embodiment, which follows the general inventive idea described in its entirety herein, a ratio 77 obtained from controlling manipulated variables 5, 7, may be measured by a measuring device 79. A second deviation signal 81 may be generated from a deviation of the ratio 77 from a fixed value 83. The second deviation signal 81 may be coupled into the second controller 74 so that the second controller 74 may generate the output signal 75. The output signal 75, together with the modulation signal 65, may control the second manipulated variable 7. To stabilize the first electromagnetic radiation 1, the second deviation signal 71 may be adjusted or the ratio 77 may be adjusted.

The manipulated variables 5 and/or 7 may be arranged in the cavity 9, but may alternatively be arranged outside the cavity 9, as shown in FIG. 6. FIG. 6 shows a further preferred embodiment, which is formed by the device 5000. Here, the manipulated variable 5 may be arranged outside the cavity 9. A control section, i.e. the entire controller or parts of the controller, of the device 5000 may be configured as described above or below.

The manipulated variables or control elements 5 and/or 7 may include different components to act on the optical oscillator 3, e.g. a current 84 that may be provided to operate the semiconductor laser 13, a temperature controller 85 that may be arranged at the optical oscillator 3 or at least one actuator 87 that may be configured to deform the optical oscillator 3 mechanically, in particular to deform it slightly.

The actuator 87 may be configured to adjust an optical path length of the optical oscillator 3. The actuator 87 may be configured as an electro-optic modulator, wherein a voltage applied to the electro-optic modulator may be configured to act on the electro-optic modulator to adjust the optical path length of the optical oscillator 3.

FIG. 2 shows another preferred embodiment represented by the device 1500. The embodiment shown in FIG. 2 is based on the embodiment shown in FIG. 1, wherein the modulation signal 65 is coupled into the manipulated variable 7 and a second modulation signal 66 is coupled into the manipulated variable 5. The modulation signals 65 and 66 are characterized by signal characteristics in phase opposition to each other. An amplitude of the modulation signal 65 and an amplitude of the modulation signal 66 may be adjusted to set a target state of the electromagnetic radiation 1. In the target state, the electromagnetic radiation may be free of modulation. A phase of the modulation signal 65 and a phase of the modulation signal 66 may be adjusted to adjust a target state of the electromagnetic radiation 1. In the target state, the electromagnetic radiation may be free of modulation.

In FIG. 3 a further preferred embodiment is shown, which is obtained by the device 2000. In contrast to the embodiment shown in FIG. 1, the device 2000 is configured to couple the output signal 75 into the manipulated variable 5 for controlling the manipulated variable 5 and to couple the output signal 57 into the manipulated variable 7 for controlling the manipulated variable 7.

The output signal 75 may be coupled either into the manipulated variable 5 or into the manipulated variable 7 and the output signal 57 may be coupled into the respective other manipulated variable 5 or 7. It may also be the case that the output signal 75 and the output signal 57 are coupled into the manipulated variable 5 or it may be the case that the output signal 75 and the output signal 57 are coupled into the manipulated variable 7. The modulation signal 65 may be coupled into the manipulated variable 5 or into the manipulated variable 7. In this case, the manipulated variable 5 may have a response time that is longer than the response time of the manipulated variable 7. In one embodiment, however, the response time of the manipulated variable 7 may also be longer than the response time of the manipulated variable 5. The controller 55 may generate at least one output signal 57 that may be provided for the aforementioned control activity. In one embodiment, the controller may include at least two outputs for generating an output signal 57 and an output signal 58 that may be provided for the aforementioned control activity. The output signal 58 may be coupled into the manipulated variable 5 for controlling the manipulated variable 5, and the output signal 57 may be coupled into the manipulated variable 7 for controlling the manipulated variable 7. In one embodiment, the output signal 58 may be coupled into the manipulated variable 7 for controlling the manipulated variable 7, and the output signal 57 may be coupled into the manipulated variable 5 for controlling the manipulated variable 5.

In an embodiment, in which the manipulated variable 5 has a response time that is longer than the response time of the manipulated variable 7, and the output signal 58 is coupled into the manipulated variable 5 for controlling the manipulated variable 5 and the output signal 57 is coupled into the manipulated variable 7 for controlling the manipulated variable 7, the controller 55 may be configured to generate an output signal 58 that has a greater amplitude than the output signal 57, in particular the controller 55 may be configured to generate an output signal 58 that has a smaller frequency bandwidth than the output signal 57 than the output signal 57, in particular the controller 55 may be configured to generate an output signal 58 that has a smaller frequency bandwidth than the output signal 57, in particular the controller 55 may be configured to generate an output signal 58 that has a slower temporal change in amplitude and/or frequency and/or phase than the output signal 57.

In an embodiment, in which the manipulated variable 5 has a response time that is shorter than the response time of the manipulated variable 7, and the output signal 58 is coupled into the manipulated variable 5 for controlling the manipulated variable 5 and the output signal 57 is coupled into the manipulated variable 7 for controlling the manipulated variable 7, the controller 55 may be configured to generate an output signal 58 that has a smaller amplitude than the output signal 57, in particular the controller 55 may be configured to generate an output signal 58 that has a larger frequency bandwidth than the output signal 57, in particular the controller 55 may be configured to generate an output signal 58 that has a faster temporal change in amplitude and/or frequency and/or phase than the output signal 57.

In an embodiment, in which the manipulated variable 5 has a response time that is longer than the response time of the manipulated variable 7, and the output signal 57 is coupled into the manipulated variable 5 for controlling the manipulated variable 5 and the output signal 58 is coupled into the manipulated variable 7 for controlling the manipulated variable 7, the controller 55 may be configured to generate an output signal 57 that has a greater amplitude than the output signal 58, in particular the controller 55 may be configured to generate an output signal 57 that has a smaller frequency bandwidth than the output signal 58, in particular the controller 55 may be configured to generate an output signal 57 that has a slower temporal change in amplitude and/or frequency and/or phase than the output signal 58.

In an embodiment, in which the manipulated variable 5 has a response time that is shorter than the response time of the manipulated variable 7, and the output signal 57 is coupled into the manipulated variable 5 for controlling the manipulated variable 5 and the output signal 58 is coupled into the manipulated variable 7 for controlling the manipulated variable 7, the controller 55 may be configured to generate an output signal 57 that has a smaller amplitude than the output signal 58, in particular the controller 55 may be configured to generate an output signal 57 that has a larger frequency bandwidth than the output signal 58, in particular the controller 55 may be configured to generate an output signal 57 that has a faster temporal change in amplitude and/or frequency and/or phase than the output signal 58.

The control sequences or components of the device 1000 already described above may also be provided in the device 2000. A control section, i.e., the entire controller or parts of the controller, of the device 2000 may be as described above or below.

In FIG. 4, a further preferred embodiment is shown, which is obtained by the device 3000. Here, a manipulated variable, e.g. the manipulated variable 7, may be controlled with the output signal 58. Furthermore, another manipulated variable, e.g. the manipulated variable 5, may be controlled with the second deviation signal 71 or 81, as well as with the output signal 57. The output signal 75 may be coupled either into the manipulated variable 5 or into the manipulated variable 7 and the output signal 57 may be coupled into the respective other manipulated variable 5 or 7. The control sequences or components of other embodiments already described above, in particular of the device 1000, may also be provided in the device 3000. A control section, i.e. the entire controller or parts of the controller, of the device 3000 may be as described above or below.

The output signal 58 is coupled into the demodulation unit 61. The modulation signal 65 generated by the modulation unit 63 is provided to the demodulation unit 61 to generate the second deviation signal 71 indicating a deviation from the fixed value 73 at the second output 69.

The output signal 58 is configured to control another control element, e.g. the manipulated variable 7, with a larger dynamic range in order to keep the output signal 57 in the center of its dynamic range.

The controller 55 may generate at least the output signal 57, which may be provided for the aforementioned control activity. In one embodiment, the controller may include at least two outputs for generating the output signal 57 and the output signal 58, which may be provided for the aforementioned control activity. In one embodiment, the output signal 58 may be coupled into the manipulated variable 5 for controlling the manipulated variable 5 and the output signal 57 may be coupled into the manipulated variable 7 for controlling the manipulated variable 7. In one embodiment, the output signal 58 may be coupled into the manipulated variable 7 for controlling the manipulated variable 7 and the output signal 57 may be coupled into the manipulated variable 5 for controlling the manipulated variable 5.

In an embodiment, in which the manipulated variable 5 has a response time that is longer than the response time of the manipulated variable 7, and the output signal 58 is coupled into the manipulated variable 5 for controlling the manipulated variable 5 and the output signal 57 is coupled into the manipulated variable 7 for controlling the manipulated variable 7, the controller 55 may be configured to generate an output signal 58 that has a greater amplitude than the output signal 57, in particular the controller 55 may be controlled to generate an output signal 58 that has a smaller frequency bandwidth than the output signal 57, in particular the controller 55 may be configured to generate an output signal 58 that has a smaller frequency bandwidth than the output signal 57, in particular the controller 55 may be configured to generate an output signal 58 that has a slower temporal change in amplitude and/or frequency and/or phase than the output signal 57.

In an embodiment, in which the manipulated variable 5 has a response time that is shorter than the response time of the manipulated variable 7, and the output signal 58 is coupled into the manipulated variable 5 for controlling the manipulated variable 5 and the output signal 57 is coupled into the manipulated variable 7 for controlling the manipulated variable 7, the controller 55 may be configured to generate an output signal 58 that has a smaller amplitude than the output signal 57, in particular the controller 55 may be configured to generate an output signal 58 that has a larger frequency bandwidth than the output signal 57, in particular the controller 55 may be configured to generate an output signal 58 that has a faster temporal change in amplitude and/or frequency and/or phase than the output signal 57.

In an embodiment, in which the manipulated variable 5 has a response time that is longer than the response time of the manipulated variable 7, and the output signal 57 is coupled into the manipulated variable 5 for controlling the manipulated variable 5 and the output signal 58 is coupled into the manipulated variable 7 for controlling the manipulated variable 7, the controller 55 may be configured to generate an output signal 57 that has a greater amplitude than the output signal 58, in particular the controller 55 may be configured to generate an output signal 57 that has a smaller frequency bandwidth than the output signal 58, in particular the controller 55 may be configured to generate an output signal 57 that has a smaller frequency bandwidth than the output signal 58, in particular the controller 55 may be configured to generate an output signal 57 that has a slower temporal change in amplitude and/or frequency and/or phase than the output signal 58.

In an embodiment, in which the manipulated variable 5 has a response time that is shorter than the response time of the manipulated variable 7, and the output signal 57 is coupled into the manipulated variable 5 for controlling the manipulated variable 5 and the output signal 58 is coupled into the manipulated variable 7 for controlling the manipulated variable 7, the controller 55 may be configured to generate an output signal 57 that has a smaller amplitude than the output signal 58, in particular the controller 55 may be configured to generate an output signal 57 that has a larger frequency bandwidth than the output signal 58, in particular the controller 55 may be configured to generate an output signal 57 that has a faster temporal change in amplitude and/or frequency and/or phase than the output signal 58.

FIG. 5 shows another preferred embodiment implemented by the device 4000. Here, a third manipulated variable 89 may be provided such that the device 4000 includes three manipulated variables 5, 7, 89. The control sequences or components of other embodiments already described above, in particular of the device 1000, may also be provided in the device 4000. A control section, i.e. the entire controller or parts of the controller, of the device 4000 may be as described above or below. The modulation signal 65 may be coupled into the third manipulated variable 89, and the output signal 75 may be coupled into the manipulated variable 7. The output signal 57 may be coupled into the manipulated variable 5 or 89. The output signal 58 may be coupled into the manipulated variable 5 or 89. In particular, the three manipulated variables 5, 7, 89 may affect together the optical oscillator 3 and may thus have an effect on the electromagnetic radiation 1, for adjusting the electromagnetic radiation 1. However, the three manipulated variables 5, 7, 89 may also affect, individually or in combination of two manipulated variables, on the optical oscillator 3 and may thus have an effect on the electromagnetic radiation 1, for adjusting the electromagnetic radiation 1.

The controller 55 may generate at least one output signal 57, which may be provided for the aforementioned control activity. In one embodiment, the controller may include at least two outputs for generating an output signal 57 and an output signal 58 that may be provided for the aforementioned control activity. The output signal 58 may be coupled into the manipulated variable 5 for controlling the manipulated variable 5, and the output signal 57 may be coupled into the manipulated variable 89 for controlling the manipulated variable 89. In one embodiment, the output signal 58 may be coupled into the manipulated variable 89 for controlling the manipulated variable 89, and the output signal 57 may be coupled into the manipulated variable 5 for controlling the manipulated variable 5.

In an embodiment, in which the manipulated variable 5 has a response time that is longer than the response time of the manipulated variable 89, and the output signal 58 is coupled into the manipulated variable 5 for controlling the manipulated variable 5 and the output signal 57 is coupled into the manipulated variable 89 for controlling the manipulated variable 89, the controller 55 may be configured to generate an output signal 58 that has a greater amplitude than the output signal 57, in particular the controller 55 may be configured to generate an output signal 58 that has a smaller frequency bandwidth than the output signal 57, in particular the controller 55 may be configured to generate an output signal 58 that has a smaller frequency bandwidth than the output signal 57, in particular the controller 55 may be configured to generate an output signal 58 that has a slower temporal change in amplitude and/or frequency and/or phase than the output signal 57.

In an embodiment, in which the manipulated variable 5 has a response time that is shorter than the response time of the manipulated variable 89, and the output signal 58 is coupled into the manipulated variable 5 for controlling the manipulated variable 5 and the output signal 57 is coupled into the manipulated variable 89 for controlling the manipulated variable 89, the controller 55 may be configured to generate an output signal 58 that has a smaller amplitude than the output signal 57, in particular the controller 55 may be configured to generate an output signal 58 that has a larger frequency bandwidth than the output signal 57, in particular the controller 55 may be configured to generate an output signal 58 that has a faster temporal change in amplitude and/or frequency and/or phase than the output signal 57.

In an embodiment, in which the manipulated variable 5 has a response time that is longer than the response time of the manipulated variable 89, and the output signal 57 is coupled into the manipulated variable 5 for controlling the manipulated variable 5 and the output signal 58 is coupled into the manipulated variable 89 for controlling the manipulated variable 89, the controller 55 may be configured to generate an output signal 57 that has a greater amplitude than the output signal 58, in particular the controller 55 may be configured to generate an output signal 57 that has a smaller frequency bandwidth than the output signal 58, in particular the controller 55 may be configured to generate an output signal 57 that has a smaller frequency bandwidth than the output signal 58, in particular the controller 55 may be configured to generate an output signal 57 that has a slower temporal change in amplitude and/or frequency and/or phase than the output signal 58.

In an embodiment, in which the manipulated variable 5 has a response time that is shorter than the response time of the manipulated variable 89, and the output signal 57 is coupled into the manipulated variable 5 for controlling the manipulated variable 5 and the output signal 58 is coupled into the manipulated variable 89 for controlling the manipulated variable 89, the controller 55 may be configured to generate an output signal 57 that has a smaller amplitude than the output signal 58, in particular the controller 55 may be configured to generate an output signal 57 that has a larger frequency bandwidth than the output signal 58, in particular the controller 55 may be configured to generate an output signal 57 that has a faster temporal change in amplitude and/or frequency and/or phase than the output signal 58.

FIG. 7 shows an embodiment of the optical oscillator 3, wherein the optical oscillator 3 may include the first manipulated variable 5 as well as the second manipulated variable 7, but may also include further manipulated variables, such as the third manipulated variable 89 already described above (not shown in FIG. 7). Furthermore, the optical oscillator 3 may be enclosed by the cavity 9, wherein the cavity 9 may have a length 11. Here, each component of the optical oscillator 3 may be used independently of the other components of the optical oscillator 3, in combination with the optical oscillator 3. However, more than one of the components may also be used together with the optical oscillator 3. Further components of the optical oscillator 3 shown in FIG. 7 will now be described in connection with the device 6000 shown in FIG. 8. The components of the optical oscillator 3 shown in FIG. 7 may be used in any optical oscillator 3 of the embodiments described herein, particularly in optical oscillators 3 of the embodiments shown in FIG. 1, 2, 3, 4, 5, 6 or 9.

In FIG. 8, there is shown an advantageous device 6000 according to the invention for stabilizing electromagnetic radiation 1 from the optical oscillator 3, which may enable an advantageous method according to the invention for stabilizing electromagnetic radiation 1 from the optical oscillator 3. The optical oscillator 3 shown in FIG. 8 is shown in a simplified embodiment, with the detailed embodiment of the optical oscillator 3 being shown in FIG. 7. However, the term detailed is not to be interpreted so as to mean that the optical oscillator shown in FIG. 7 could not be expanded to include additional components, such as additional manipulated variables. The advantageous device 6000 includes additional components, and the components may also be provided in the devices 1000, 2000, 3000, 4000, as well as 5000, and may be combined with the devices 1000, 2000, 3000, 4000, as well as 5000 in a modular fashion. For example, the semiconductor laser 13 may include additional components and/or one or more filters may be provided in the cavity 9. This will now be described in further detail below.

Here, the optical oscillator 3 may in particular be a laser. The optical oscillator 3 may be arranged in the device 6000 according to the invention to generate the electromagnetic radiation 1. Here, the optical oscillator 3 may further include the semiconductor laser 13, wherein the semiconductor laser 13 may include a first surface 91 and a second surface 93, and the semiconductor laser 13 may be arranged within the cavity 9. Adjacent to the first surface 91 of the semiconductor laser 13, an adjustable wavelength filter 95 may further be disposed, wherein the wavelength filter may also be disposed within the cavity 9.

The adjustable wavelength filter 95 may be a volume holographic Bragg grating (VHBG), wherein the adjustable wavelength filter 95 may be configured to select at least one wavelength of the electromagnetic radiation 1. A selection of the at least one wavelength of the electromagnetic radiation 1 may be achieved by tilting the wavelength filter 95 with respect to a propagation direction of the electromagnetic radiation 1. In one embodiment, selecting the at least one wavelength of electromagnetic radiation 1 may be achieved by controlling the temperature of the wavelength filter 95. In this regard, an expansion or a contraction of the wavelength filter 95 may be achieved by heating or cooling the wavelength filter 95, thereby creating a transmission or reflection property for an electromagnetic radiation 1 of a selected wavelength or a selected wavelength continuum, wherein the electromagnetic radiation of a selected wavelength or a selected wavelength continuum may at least partially penetrate the wavelength filter 95 or is at least partially reflected by the wavelength filter 95. In an advantageous embodiment, a wavelength filter 95 may be tilted with respect to a propagation direction of the electromagnetic radiation 1 in order to create a particularly advantageous alternative to achieve a selection of the at least one wavelength of the electromagnetic radiation 1. A temperature of the wavelength filter 95 may be controlled.

Alternatively, the adjustable wavelength filter 95 may be configured as a frequency selective grating, wherein selection of the at least one wavelength of electromagnetic radiation 1 may be achieved by a tilted frequency selective grating that is tilted with respect to the direction of propagation of the electromagnetic radiation 1.

In an alternative embodiment, the adjustable wavelength filter 95 may be implemented as a dielectric filter, wherein selecting the at least one wavelength of the electromagnetic radiation 1 may be achieved by an optical path length of the dielectric filter in a longitudinal direction with respect to the propagation direction of the electromagnetic radiation 1, wherein further selecting the at least one wavelength of the electromagnetic radiation 1 may be achieved by a dielectric filter tilted with respect to a propagation direction of the electromagnetic radiation 1. The optical path length of the dielectric filter may be obtained by means of tilting or by changing the temperature of the dielectric filter. In particular, however, the optical path length of the dielectric filter may also be changed by changing a temperature of the dielectric filter, which may cause the dielectric filter to expand or contract, and thus the optical path length of the dielectric filter may be changed in a longitudinal direction with respect to the propagation direction of the electromagnetic radiation 1. In particular, not only the optical path length of the dielectric filter may be changed by varying the temperature, but also optical path lengths of the aforementioned adjustable wavelength filters.

An actuator 97 may be disposed adjacent to the adjustable wavelength filter 95, and the actuator 97 may also be disposed in the cavity 9. In particular, the cavity 9 or the optical oscillator 3 may be bounded by a first surface 99 and a second surface 101. Here, the first surface 99 of the cavity 9 and/or the second surface 101 of the cavity 9 may be coupled to the actuator 97, wherein in the advantageous embodiment of FIG. 8, only the first surface 99 of the cavity 9 is coupled to the actuator 97.

Furthermore, the first manipulated variable 5 may be an electric current, in particular a change of an electric current, wherein the semiconductor laser 13 may be electronically pumped by this electric current. A change in the absolute value of the electric current, which may be provided to pump the semiconductor laser 13, may lead to a shortening or a lengthening of the at least one wavelength of the electromagnetic radiation 1. However, the manipulated variable 5 may also be understood as an externally adjustable current source, in particular a driver, wherein the manipulated variable 5 may be coupled to the semiconductor laser 13. In particular, the actuator 97 may be based on a piezoelectric effect, wherein the piezoelectric effect may be activated by a voltage applied to the actuator 97 from the outside. In this case, therefore, the manipulated variable 7 may be a voltage source, for example a voltage power supply, configured to apply a voltage to the actuator 97. However, the actuator 97 may also be an electro-optical modulator. In this case, the electro-optical modulator may be an optical device based on an electro-optical effect, wherein the electro-optical effect may enable, by a signal applied from outside to the electro-optical modulator, to act on an amplitude or a phase of the electromagnetic radiation 1. In this embodiment, the manipulated variable 7 would be represented by the signalling element for controlling the electro-optical modulator.

Furthermore, a comparison unit 103 may be provided in the device 6000 according to the invention, wherein the comparison unit 103 may further include a wavelength converter 105 and a wavelength comparator 107. The comparison unit 103 may typically include a first input 105 for coupling the electromagnetic radiation 1 into the comparison unit 103. Further, the comparison unit 103 may include a second input 107 to couple an electromagnetic radiation 109 from a first reference source 111 into the comparison unit 103. Further, the comparison unit 103 may include a third input 113 to couple in an electromagnetic radiation 115 of a second reference source 117. Finally, the comparison unit 103 may include a first output 119, from which the phase deviation signal 35 and/or the frequency deviation signal 37 may be coupled out. Here, the phase deviation signal 35 may be generated by the phase detector already described above. Furthermore, the frequency deviation signal 37 may be generated by the analog mixer already described above.

An input 121 may be configured to receive the phase deviation signal 35 and/or the frequency deviation signal 37, wherein the input 121 may forward the phase deviation signal 35 and/or the frequency deviation signal 37 to a first controller 123 and/or to a second controller 125. Further, a control unit 127 may be provided to control the first controller 123 and/or the second controller 125. Further, a first superposition unit 129 may be configured to receive an output signal 131 from the second controller 125.

Furthermore, the first superposition unit 129 may be configured to couple the output signal 131 of the second controller 125 into the second manipulated variable 7. Thus, in particular, the actuator 97 may be configured to be controlled by the second controller 125 by receiving the output signal 131 of the second controller 125 from the manipulated variable 7, with the manipulated variable 7 in turn controlling the actuator 97. A second superposition unit 133 may be configured to receive an output signal 135 of the first controller 123. Here, the first manipulated variable 5 may be configured to receive the output signal 135 of the first controller 123 via the first superposition unit 133. Thus, the semiconductor laser 13 may be controlled by the output signal 135 of the first controller 123 in that the output signal 135 of the first controller 123 controls the manipulated variable 5 via the first superposition unit 133, wherein the manipulated variable 5 may control the semiconductor laser 13.

Further, a demodulation unit 137 may be provided, which may be further configured to receive the output signal 135 of the first controller 123. Further, a modulation unit 139 may be provided, which may be configured to generate a modulation 141, wherein the modulation 141 may be a time varying signal. In particular, the first superposition unit 129 may be configured to receive the modulation 141. Advantageously, the first superposition unit 129 may be configured to generate a superposition 143, wherein the superposition 143 may be generated by the first superposition unit 129 from the modulation 141 and the output signal 131 of the second controller 125. In particular, the second manipulated variable 7 is configured to receive the superposition 143. In particular, therefore, the actuator 97 may be controlled by the second manipulated variable 7 through the superposition 143.

Further, the demodulation unit 137 may be configured to receive the modulation 141 from the modulation unit 139. Here, the demodulation unit 137 may generate a demodulation signal 145 from a fixed value 146. Further, the device 6000 may include a third controller 147, which may be configured to be controlled by the demodulation signal 145. Further, the third controller 147 may be configured to generate an output signal 149. Finally, the second superposition unit 133 may be configured to receive the output signal 149 from the third controller 147. In particular, the second superposition unit 133 may be configured to generate a second superposition 151, wherein the second superposition 151 may be a superposition of the output signal 149 of the third controller 147 and the output signal 135 of the first controller 123.

In particular, the first manipulated variable 5 may be configured to be controlled by the second superposition 151. The semiconductor laser 13 may thus be controlled by the second superposition 151 via the manipulated variable 5.

Advantageously, a temperature element 153 may be provided in the device 6000 according to the invention, wherein the temperature element 153 may be coupled to the cavity 9, in particular the temperature element 153 may be coupled to an outer wall of the cavity 9. In this way, the cavity 9 may be heated to achieve a change in the length 11 of the cavity 9 by means of a thermal expansion. By this, the at least one wavelength of the electromagnetic radiation 1 may be adjusted. In particular, by heating the cavity 9 by the temperature element 153 towards a temperature of the cavity 9, which may be above a room temperature, a temperature stabilization of the cavity 9 may be achieved and thus a temperature stabilization of the optical oscillator 3 may be achieved. The temperature element 153 may also include a Peltier element, wherein it would be feasible to cool the cavity 7 to achieve a change in the length 11 of the cavity 9 by means of thermal contraction. The temperature element 153 may represent another manipulated variable/control element and may be controlled by the controller 123 or 125, although this is not explicitly shown in FIG. 8 or 9. The adjustable wavelength filter 95 may represent another manipulated variable and may be controlled by the controller 123 or 125, although this is not explicitly shown in FIG. 8 or 9.

In this case, in order to stabilize the first electromagnetic radiation 1, the demodulation signal 145 may be controlled. The demodulation signal 145 may be a deviation signal from the fixed value 146.

FIG. 9 shows a further embodiment of the device according to the invention for stabilizing electromagnetic radiation 1 from the optical oscillator 3. This embodiment is implemented by the device 7000 shown. To arrive at the advantageous embodiment shown in FIG. 9, the advantageous device 6000 according to the invention of FIG. 8 may be modified, wherein a modification of the advantageous device 6000 according to the invention of FIG. 8 may include the device 6000 of FIG. 8 without the second controller 123 and without the output signal 131 and may further include a diode driver 155, wherein the diode driver 155 may be configured to generate an output signal 157, wherein the output signal 157 may include a voltage and/or a current, wherein advantageously the output signal 157 of the diode driver 155 may include a voltage pulse and/or a current pulse, and wherein the modification may further include the superposition unit 129, wherein the superposition unit 129 may be configured to superpose the modulation 141 with the output signal 149 of the third controller 147, to generate at least a first superposition 143, rather than the second superposition unit 133 being adapted to superpose the output signal 135 of the first controller 123 with the output signal 149 of the third controller 147 to generate the second superposition 151, wherein the modification may further include the second superposition unit 133, wherein the second superposition unit 133 may be configured to superpose the output signal 157 of the diode driver 155 with the output signal 135 of the first controller 123 to generate the second superposition 151 for controlling the at least one first manipulated variable 5 of the optical oscillator 3.

Thus, the device 6000 according to the invention for stabilizing the electromagnetic radiation 1 of the optical oscillator 3, in particular of the laser, shown in FIG. 8 and described above may be used to perform the advantageous method according to the invention for stabilizing the electromagnetic radiation 1 of the optical oscillator 3, in particular of the laser.

In particular, the aforementioned method may include generating the electromagnetic radiation 1 with the semiconductor laser 13, wherein first the electromagnetic radiation 1 may be excited in the cavity 9 and the at least one wavelength of the electromagnetic radiation 1 may be selected by means of the adjustable wavelength filter 95 arranged in the cavity 9. Further, the electromagnetic radiation 1 may be coupled out of the first surface 99 that is partially transparent to the electromagnetic radiation 1 for generating the phase deviation signal 35 and/or the frequency deviation signal 37.

For this purpose, the electromagnetic radiation 1 may first be coupled into the comparison unit 103, wherein further the electromagnetic radiation 109 of the first reference source 111 may also be coupled into the comparison unit 103 for generating at least one frequency difference between at least one frequency of the electromagnetic radiation 1 and at least one frequency of the electromagnetic radiation 109 of the first reference source 111. The generation of the at least one frequency difference between the at least one frequency of the electromagnetic radiation 1 and the at least one frequency of the electromagnetic radiation 109 of the first reference source 111 may advantageously be enabled by the wavelength converter 105, wherein the wavelength converter 105 may in particular be an analog mixer. For generating the frequency deviation signal 37, the wavelength comparator 107 may be used, wherein when generating the frequency deviation signal 37 by the wavelength comparator 107, the wavelength comparator 107 may also be an analog mixer. For this purpose, the wavelength comparator or the analog mixer 107 may generate a further frequency difference between, on the one hand, the frequency difference between the at least one frequency of the electromagnetic radiation 1 and the at least one frequency of the electromagnetic radiation 109 of the first reference source 111 and, on the other hand, the at least one frequency of the electromagnetic radiation 115 of the second reference source 117. Finally, the aforementioned further frequency difference between, on the one hand, the frequency difference between the at least one frequency of the electromagnetic radiation 1 and the at least one frequency of the electromagnetic radiation 109 of the first reference source 111 and, on the other hand, the at least one frequency of the electromagnetic radiation 115 of the second reference source 117 may represent the frequency deviation signal 37. The phase deviation signal 35 may be generated essentially in the same way as the frequency deviation signal 37, but now the wavelength comparator 107 may be the digital phase detector already described above.

If the controllers 123 and 125 are now controlled by the phase deviation signal 35 and/or the frequency deviation signal 37, the controller 123 may generate the output signal 135 and/or the controller 125 may generate the output signal 131, for obtaining the superposition 151 and/or the superposition 143, wherein further the superposition 143 and/or the superposition 151 may be generated by a functionality of the above described device 6000, 7000 for stabilizing the electromagnetic radiation 1. The superposition 143 may control the manipulated variable 7 whereas the superposition 151 may control the manipulated variable 5. Hereby, it may be feasible to adjust the actuator 97 and/or the semiconductor laser 13 either individually or simultaneously, since the manipulated variable 5 may be connected to the semiconductor laser 13 and/or the manipulated variable 7 may be connected to the actuator 97.

Advantageously, a control unit 127 may further be provided for controlling a ratio between controlling the second manipulated variable 7 and controlling the first manipulated variable 5. In particular, the control unit 127 may control the first controller 123 and/or the second controller 125. For this purpose, the control unit 127 may include a feedback loop, wherein the feedback loop of the control unit 127 may be configured to minimize the phase deviation signal 35 and/or the frequency deviation signal 37 or to control it to at least a fixed value of the phase deviation signal 35 and/or to control it to at least a fixed value of the frequency deviation signal 37. To this end, the phase deviation signal 35 and/or the frequency deviation signal 37 may be measured by the control unit 127. Further, the control unit 127 may control the first controller 123 and/or the second controller 125, for minimizing the phase deviation signal 35 and/or the frequency deviation signal 37 or for controlling the phase deviation signal 35 and/or the frequency deviation signal 37 to a fixed value.

Furthermore, the further embodiment of the device 7000 according to the invention for stabilizing the electromagnetic radiation 1 of the optical oscillator 3, in particular the laser, shown in FIG. 9 and described above may be used to carry out an embodiment according to the invention of a method for stabilizing the electromagnetic radiation 1 of the optical oscillator 3, in particular the laser.

In this regard, the method according to the invention that may be performed by using the device 6000 shown in FIG. 8 may be modified so as to arrive at the method that may be performed by using the embodiment of the device 7000 shown in FIG. 9. Here, a modification of the method according to the invention may include deactivating the second controller 125, for turning off the output signal 131, and providing a diode driver 155, and superimposing the modulation 141 on the output signal 149 of the third controller 147, for generating the first superposition 143, instead of superimposing the output signal 149 of the third controller 147 on the output signal 135 of the first controller 123, for generating the second superposition 151, wherein further an output signal 157 of the diode driver 155 may be superimposed with the output signal 135 of the first controller 123, for generating the second superimposition 151, for controlling the at least one first manipulated variable 5 of the optical oscillator 3, wherein the output signal 157 of the diode driver 155 may include a voltage and/or a current, advantageously the output signal 157 of the diode driver 155 may include a voltage pulse and/or a current pulse.

However, the process steps already described above are otherwise also applicable to the further embodiment of the device 7000 shown in FIG. 9.

In both the device 6000 shown in FIG. 8 and the embodiment of the device 7000 shown in FIG. 9, at least the actuator 97 may be provided for increasing a dynamic range of the control in that at least the actuator 97 may be provided for realizing a large frequency and/or phase deviation.

The devices shown in FIGS. 8 and 9 may include components, particularly electronic components, that include analog circuit components, although the components may also include digital circuit components. Similarly, the components may include both analog and digital circuit components. Similarly, analog circuit components may be substituted for digital circuit components, or conversely, digital circuit components may be substituted for analog circuit components. On the one hand, this may enable suppression of noise in the aforementioned control activity to enable a reliable control activity with the device. Thus, in addition to the wavelength comparator 107, which may be implemented as a digital phase detector, the wavelength converter 105 may also be implemented as a digital mixer instead of an analog mixer. The wavelength comparator 107 as well as the wavelength converter 105 may thus be implemented as fully digital circuits and may be implemented, for example, by means of logic on a single chip, e.g., on a field programmable gate array (FPGA) chip. Thus, except for the manipulated variables 5 as well as 7 and the optical oscillator 3, the aforementioned control regime may be realized by means of an FPGA chip. However, a logic on the FPGA chip may provide output signals to control or regulate the manipulated variables 5 as well as 7. However, the manipulated variables 5 as well as 7, may also be provided in such a way that they may also be provided by means of the logic on the FPGA chip. The FPGA chip may further include circuitry, wherein the circuitry may provide optical interfaces so that electromagnetic radiation 107 from the first reference source 111 may be coupled into the FPGA chip and also electromagnetic radiation 1 from the optical oscillator 3 may be coupled into the FPGA chip. For example, the second reference source 117 may be a voltage controlled oscillator. The aforementioned control regime is not limited to a semiconductor laser, but to any oscillator that includes a controllable output signal or that provides another controllable signal to be stabilized.

1. A method for stabilizing a first electromagnetic radiation of an optical oscillator, in particular of a first laser, comprising,
measuring a deviation between the first electromagnetic radiation of the optical oscillator and a reference and generating a first deviation signal,
controlling a first controller the first deviation signal,
setting the first deviation signal by controlling at least one first manipulated variable of at least two manipulated variables, the first manipulated variable being controlled by a first output signal of the first controller and the first manipulated variable affecting the first electromagnetic radiation of the optical oscillator,
characterized by
generating a modulation signal with a modulation unit, and controlling the first or a second manipulated variable with the modulation signal,
demodulating the first output signal the first controller with the modulation signal and generating a second deviation signal with respect to a fixed value,
controlling a second controller with the second deviation signal,
controlling one of the manipulated variables with an output signal of the second controller and setting the second deviation signal.

2. The of claim 1, wherein the deviation is minimized.

3. The method of claim 1, further comprising,
generating a second modulation signal with the modulation unit, and controlling the other of the first and second manipulated variables with the second modulation signal, wherein in particular effects of the modulation signal and the second modulation signal on the first electromagnetic radiation are in phase opposition to each other,
adjusting a phase and/or an amplitude of the modulation signal, and adjusting a phase and/or an amplitude of the second modulation signal, for providing the first electromagnetic radiation without modulation.

4. The method of claim 1, wherein the reference comprises a radio frequency reference and a second electromagnetic radiation of a second laser, and the deviation is generated as a difference between, on the one hand, a difference of the first electromagnetic radiation and the second electromagnetic radiation, and, on the other hand, the radio frequency reference.

5. The method of claim 1, wherein the deviation comprises a frequency deviation or a phase deviation.

6. The method of claim 1, wherein the reference comprises a resonator and the deviation comprises a frequency deviation or a phase deviation between a frequency or phase of the first electromagnetic radiation and a frequency or phase of the resonator.

7. The method of claim 6, wherein the resonator comprises a quality in a range between 10000 and 1000000, wherein the quality is equal to a frequency of the resonator divided by a frequency bandwidth of the resonator, and the resonator preferably comprises ULE (ultra-low expansion) spacers.

8. The method of claim 6, wherein the resonator comprises an etalon, in particular a Fabry-Perot etalon.

9. The method of claim 1, wherein the reference comprises an atomic or molecular gas and the deviation comprises a frequency deviation or a phase deviation between a frequency or phase of the first electromagnetic radiation and a frequency or phase of a resonance of the atomic or molecular gas.

10. The method of claim 1, wherein the reference comprises a frequency or phase measuring instrument, in particular a wavemeter or an interferometer, and the deviation comprises a frequency deviation or a phase deviation between a frequency or phase of the first electromagnetic radiation and a frequency or phase of the frequency or phase measuring instrument.

11. The method of claim 1, wherein the optical oscillator comprises the manipulated variables and comprises a semiconductor laser, in particular a diode laser, and the manipulated variables comprise a diode current of the diode laser and/or comprise the diode temperature of the diode laser.

12. The method of claim 1, wherein the optical oscillator comprises a first surface and a second surface, at least one of the first surface and the second surface being partially transparent to the first electromagnetic ,radiation wherein in particular the optical oscillator comprises an adjustable wavelength filter for selecting at least one wavelength of the first electromagnetic radiation.

13. The method of claim 12, wherein the manipulated variables represent at least one piezo-actuator coupled to the first surface and/or the second surface to exert a force on the first surface and/or the second surface so as to adjust the frequency or phase of the first electromagnetic radiation.

14. The method of claim 6, wherein the manipulated variables represent at least one electro-optical modulator arranged in a beam path of the optical oscillator so as to adjust the frequency or phase of the first electromagnetic radiation.

15. The method of claim 12, wherein the manipulated variables represent the adjustable wavelength filter and are configured to adjust the adjustable wavelength filter.

16. The method of claim 1, wherein at least one of the manipulated variables is external to the optical oscillator and represents an acousto-optic modulator or a frequency shifter.

17. A control device for stabilizing a first electromagnetic radiation of an optical oscillator, in particular of a first laser, comprising,
a measuring device,
a reference generator for generating a reference,
a first controller,
a second controller,
wherein the measuring device is configured to measure a deviation between the first electromagnetic radiation of the optical oscillator and the reference,
wherein the first controller is configured to be controlled by a first deviation signal and to set the deviation signal by controlling at least one first manipulated variable of at least two manipulated variables with a first output signal,
characterized by
a modulation unit designed to control the first or a second manipulated variable with a modulation signal,
a demodulation unit configured to demodulate the first output signal of the first controller with the modulation signal and to generate a second deviation signal with respect to a fixed value,
said second controller configured to be controlled by said second deviation signal and to control one of said manipulated variables with an output signal so as to set said second deviation signal.

18. A method for stabilizing a first electromagnetic radiation of an optical oscillator, in particular of a first laser, comprising,
measuring a deviation between the first electromagnetic radiation of the optical oscillator and a reference and generating a first deviation signal,
controlling a first controller with the first deviation signal,
setting the first deviation signal by controlling at least one first manipulated variable of at least two manipulated variables, the first manipulated variable being controlled by a first output signal of the first controller and the first manipulated variable affecting the first electromagnetic radiation of the optical oscillator,
characterized by
measuring a modulation index, in particular a frequency and/or phase modulation index, of at least one of the manipulated variables and generating a second deviation signal from a deviation of the modulation index from a fixed value,
controlling a second controller with the second deviation signal,
controlling one of the manipulated variables with an output signal of the second controller and setting the second deviation signal or the modulation index, wherein the modulation index is a ratio of the controlling of at least one of the manipulated variables and the effect of the at least one manipulated variable on the first electromagnetic radiation.

19. The method of claim 18, further comprising,
generating a modulation signal with a modulation unit, and controlling the first or a second manipulated variable with the modulation signal.

20. The method of claim 19, further comprising,
generating a second modulation signal with the modulation unit, and controlling the other of the first and second manipulated variables with the second modulation signal, in particular wherein an effect of the modulation signal on the first electromagnetic radiation and an effect of the second modulation signal on the first electromagnetic radiation are in antiphase to each other,
adjusting a phase and/or an amplitude of the modulation signal, and adjusting a phase and/or an amplitude of the second modulation signal, for providing the first electromagnetic radiation without modulation.
